(19) United States
(12) Patent Application Publication
(10) Pub. No.: US 2025/0157848 A1
(43) Pub. Date: May 15, 2025

(54) SUBSTRATE LIFTING APPARATUS AND SUBSTRATE PROCESSING APPARATUS INCLUDING THE SAME

(71) Applicant: SEMES CO., LTD., Chungcheongnam-do (KR)

(72) Inventors: Mun Hyeok HWANG, Chungcheongnam-do (KR); Han Bin CHOI, Chungcheongnam-do (KR)

(21) Appl. No.: 18/945,498

(22) Filed: Nov. 12, 2024

(30) Foreign Application Priority Data
Nov. 14, 2023 (KR) 10-2023-0157076

(51) Int. Cl. H01L 21/687; H01L 21/673

(52) U.S. Cl. CPC H01L 21/68742; H01L 21/67389

(57) ABSTRACT

A substrate lifting apparatus according to the present disclosure includes: a lift pin penetrating through a substrate support unit supporting a substrate in a processing space and lifting and lowering the substrate; a pin holder into which a lower portion of the lift pin is inserted; and a bellows surrounding the pin holder, wherein the pin holder is formed with a guide member whose lower portion is coupled with a bolt and guiding an air flow generated inside the bellows in a direction of the processing space.

### CROSS-REFERENCE TO RELATED APPLICATION

This application claims priority from Korean Patent Application No. 10-2023-0157076 filed on Nov. 14, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a substrate lifting apparatus and a substrate processing apparatus.

### 2. Description of the Related Art

In a process of manufacturing a semiconductor device, a semiconductor substrate goes through several processes, including a process of depositing a material layer, a process of etching the deposited material layer, a cleaning process, and a drying process. These processes are performed in a process chamber, which is a semiconductor manufacturing device.

The chamber is a reaction vessel with a sealed reaction area inside, and is installed with a chuck to fix the semiconductor substrate seated inside. In this case, the chuck may be classified into a vacuum chuck that uses vacuum or an electrostatic chuck that uses electrostatic force, depending on a gripping method of the substrate.

The substrate is transferred by a substrate transfer device into or out of the chamber. The transfer of the substrate is carried out in a state in which the substrate is lifted to be spaced apart from the chuck. To this end, the chuck is provided with a substrate lifting apparatus for lifting or lowering the substrate from the chuck.

### SUMMARY

Aspects of the present disclosure provide a substrate lifting apparatus and a substrate processing apparatus in which loosening of a pin holder may be minimized or prevented.

Aspects of the present disclosure are not limited to the aspects mentioned above, and other aspects not mentioned will be clearly understood by those skilled in the art from the following description.

According to an aspect of the present disclosure, there is provided a substrate lifting apparatus including: a lift pin penetrating through a substrate support unit supporting a substrate in a processing space and lifting and lowering the substrate; a pin holder into which a lower portion of the lift pin is inserted; and a bellows surrounding the pin holder, wherein the pin holder is formed with a guide member whose lower portion is coupled with a bolt and guiding an air flow generated inside the bellows in a direction of the processing space.

According to another aspect of the present disclosure, there is provided a substrate processing apparatus including: a chamber in which a processing space is formed; a substrate support unit provided in the processing space and supporting a substrate; a vacuum pump creating a vacuum atmosphere in the processing space; and the substrate lifting apparatus described above.

According to still another aspect of the present disclosure, there is provided a substrate processing apparatus including: a chamber in which a processing space is formed where a substrate is processed by plasma etching, an opening through which the substrate enters and exits, and an exhaust hole through which by-products generated in the processing space are discharged to the outside are formed; a substrate support unit provided in the processing space and supporting the substrate; a vacuum pump creating a vacuum atmosphere in the processing space; a substrate lifting apparatus lifting and lowering the substrate; and a plate provided below a bottom surface of the chamber to be movable up and down for lifting and lowering the substrate lifting apparatus, wherein the substrate lifting apparatus includes: a lift pin penetrating through the substrate support unit and the bottom surface of the chamber and lifting and lowering the substrate; a pin holder into which a lower portion of the lift pin is inserted, supported on the plate, and including an upper area positioned above and a lower area positioned below the upper area, a cut groove being formed in the upper area from top to bottom to facilitate the insertion of the lift pin; and a bellows surrounding the pin holder, having an inner side in contact with an outer peripheral surface of the pin holder, and supported on the plate, and the pin holder is fastened to an inner lower portion of the bellows by coupling a lower portion with a bolt, and a concave spiral groove formed along the outer peripheral surface of the pin holder to guide an air flow generated when the processing space is created in a vacuum atmosphere or when air of the processing space is discharged to the outside through the exhaust hole, and having a spiral shape inclined upward in the same direction as a direction in which the pin holder is assembled to the bolt is provided in the lower area of the pin holder.

The details of other exemplary embodiments are included in the detailed description and drawings.

Since the substrate lifting apparatus and the substrate processing apparatus according to the present disclosure may prevent a coupling of the pin holder from becoming loose, durability may be improved, and particles that may be generated due to bolt loosening may be reduced.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view illustrating a semiconductor element manufacturing facility equipped with a substrate processing apparatus according to some exemplary embodiments of the present disclosure;

FIG. 2 is a view illustrating a substrate processing apparatus provided with a substrate lifting apparatus according to some exemplary embodiments of the present disclosure;

FIG. 3 is a view illustrating area A of FIG. 2;

FIG. 4 is a view illustrating a state in which a substrate is lifted in the substrate processing apparatus provided with the substrate lifting apparatus according to some exemplary embodiments of the present disclosure;

FIG. 5 is a view illustrating area B of FIG. 4;

FIG. 6 is a view illustrating a pin holder of a substrate lifting apparatus according to a first exemplary embodiment of the present disclosure;

FIG. 7 is a view illustrating a pin holder of a substrate lifting apparatus according to a second exemplary embodiment of the present disclosure; and

FIG. 8 is a view illustrating a pin holder according to a comparative example.

### DETAILED DESCRIPTION OF THE EMBODIMENTS

Hereinafter, exemplary embodiments of the present disclosure will be described in detail with reference to the accompanying drawings. Advantages and features of the present disclosure and methods of achieving the same will become apparent with reference to the embodiments described below in detail in conjunction with the accompanying drawings. However, the present disclosure is not limited to exemplary embodiments to be described below, but may be implemented in various different forms, these exemplary embodiments will be provided only in order to make the present disclosure complete and allow those skilled in the art to completely recognize the scope of the present disclosure, and the present disclosure will be defined by the scope of the claims. Throughout the specification, like reference numerals denote like components.

The terms used herein are for the purpose of describing the exemplary embodiments and are not intended to limit the present disclosure. In the present specification, a singular form includes a plural form unless explicitly stated otherwise. Components, steps, operations, and/or elements mentioned by the terms “comprise” and/or “comprising” used in the present disclosure do not exclude the existence or addition of one or more other components, steps, operations, and/or elements.

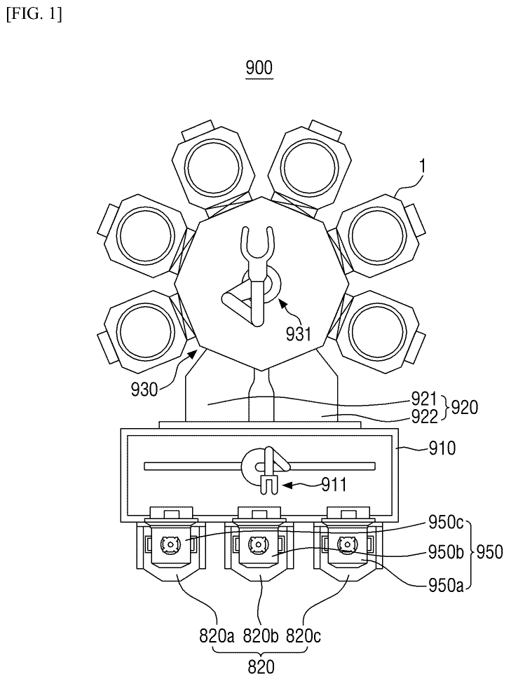

FIG. 1 is a view illustrating a semiconductor element manufacturing facility equipped with a substrate processing apparatus according to some exemplary embodiments of the present disclosure.

Referring to FIG. 1, a semiconductor element manufacturing facility 900 may include a load port module 820, an index module 910, a load-lock chamber 920, a transfer chamber 930, and a substrate processing apparatus 1 of the present exemplary embodiment as a process chamber.

The semiconductor element manufacturing facility 900 is a system that processes a plurality of substrates (e.g., wafers) through various processes such as an etching process and a cleaning process. The semiconductor element manufacturing facility 900 may be implemented as a multi-chamber type substrate processing system including transfer robots 911 and 931 responsible for transferring the substrates and a plurality of substrate processing apparatuses 1, which are substrate processing modules provided around the transfer robots.

A container 950 (e.g., Front Opening Unified Pod (FOUP)) on which a plurality of substrates are mounted is seated on the load port module 820. A plurality of such load port modules 820 may be disposed in front of the index module 910.

When the plurality of load port modules 820 are disposed in front of the index module 910, different items may be mounted on the container 950 mounted on each load port module 820. When three load port modules 820 are disposed, for example, in front of the index module 910, a wafer-type sensor (not illustrated) may be mounted on a first container 950a, which is seated on a first load port 820a on the left, a substrate may be mounted on a second container 950b, which is seated on a second load port 820b on the center side, and consumable parts (not illustrated) may be mounted on a third container 950c, which is seated on a third load port 820c on the right. However, the present exemplary embodiment is not limited thereto. The containers 950a, 950b, and 950c mounted on each load port 820a, 820b, and 820c may be changed as needed, such that the same item may be mounted thereon.

The index module 910 is disposed between the load port module 820 and the load-lock chamber 920 and interfaces to transfer the substrate between the container 950 on the load port module 820 and the load-lock chamber 920. The index module 910 may be implemented as a front end module (FEM), but is not limited thereto.

The index module 910 may include a first transfer robot 911 responsible for transferring the substrate. Such a first transfer robot 911 may operate in an atmospheric pressure environment and may transfer the substrate between the container 950 and the load-lock chamber 920.

The load-lock chamber 920 may serve as a buffer between an input port and an output port on the semiconductor element manufacturing facility 900. The load-lock chamber 920 may have a buffer stage therein where the substrate temporarily waits.

A plurality of load-lock chambers 920 may be provided between the index module 910 and the transfer chamber 930. In the present exemplary embodiment, for example, two load-lock chambers 921 and 922, such as a first load-lock chamber 921 and a second load-lock chamber 922, may be provided between the index module 910 and the transfer chamber 930.

The first load-lock chamber 921 and the second load-lock chamber 922 may be disposed in a horizontal direction between the index module 910 and the transfer chamber 930. For example, the first load-lock chamber 921 and the second load-lock chamber 922 may be provided as a mutually symmetrical single-layer structure disposed side by side in the left and right directions. Alternatively, the first load-lock chamber 921 and the second load-lock chamber 922 may also be disposed in a vertical direction between the index module 910 and the transfer chamber 930.

The first load-lock chamber 921 may transfer the substrate from the index module 910 to the transfer chamber 930, and the second load-lock chamber 922 may transfer the substrate from the transfer chamber 930 to the index module 910. However, the present exemplary embodiment is not limited thereto. The first load-lock chamber 921 may also transfer the substrate from the transfer chamber 930 to the index module 910, and the second load-lock chamber 922 may also transfer the substrate from the index module 910 to the transfer chamber 930.

The load-lock chamber 920 may have a substrate loaded or unloaded by a second transfer robot 931 of the transfer chamber 930. The load-lock chamber 920 may have a substrate loaded or unloaded by the first transfer robot 911 of the index module 910.

The load-lock chamber 920 may maintain pressure while changing the inside thereof to a vacuum environment and an atmospheric pressure environment using a gate valve, etc. Through this, the load-lock chamber 920 may prevent an internal air pressure state of the transfer chamber 930 from changing.

Specifically, when the substrate is loaded or unloaded by the second transfer robot 931, the inside of the load-lock chamber 920 may be formed in a vacuum environment that is the same as (or close to) that of the transfer chamber 930. In addition, when the substrate is loaded or unloaded by the first transfer robot 911 (i.e., when an unprocessed substrate is supplied from the first transfer robot 911 or a previously processed substrate is transferred to the index module 910), the inside of the load-lock chamber 920 may be formed in an atmospheric pressure environment.

The transfer chamber 930 transfers the substrate between the load-lock chamber 920 and the substrate processing apparatus 1. To this end, the transfer chamber 930 may include at least one second transfer robot 931.

The second transfer robot 931 transfers the unprocessed substrate from the load-lock chamber 920 to the substrate processing apparatus 1, or transfers the previously processed substrate from the substrate processing apparatus 1 to the load-lock chamber 920. To this end, each side of the transfer chamber 930 may be connected to the load-lock chamber 920 and the plurality of substrate processing apparatuses 1.

Meanwhile, the second transfer robot 931 may operate in a vacuum environment and may be provided to freely rotate.

The substrate processing apparatus 1 may process a substrate. The substrate processing apparatus 1 may be implemented as an etching chamber that processes a substrate using an etching process, and may be implemented as a plasma reaction chamber that etches a substrate using a plasma process, for example.

A plurality of substrate processing apparatuses 1 may be disposed around the transfer chamber 930. In this case, each substrate processing apparatus 1 may receive a substrate from the transfer chamber 930, perform processing on the substrate, and provide the processed substrate to the transfer chamber 930.

The substrate processing apparatus 1 may be formed in a cylindrical shape. Such a substrate processing apparatus 1 may have a surface made of alumite with an anodized film formed thereon, and the inside thereof may be airtight. On the other hand, the substrate processing apparatus 1 may also be formed in a shape other than the cylindrical shape in the present exemplary embodiment.

Hereinafter, the substrate processing apparatus will be described in detail with reference to the drawings.

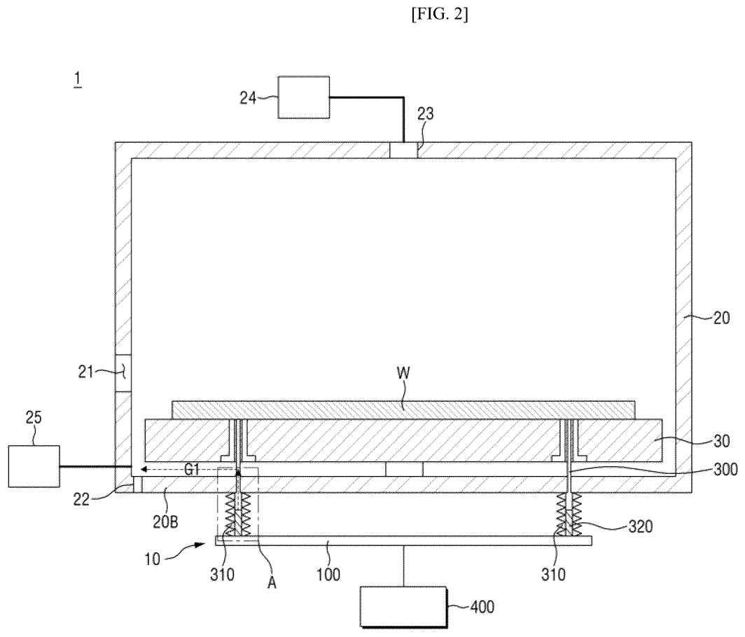

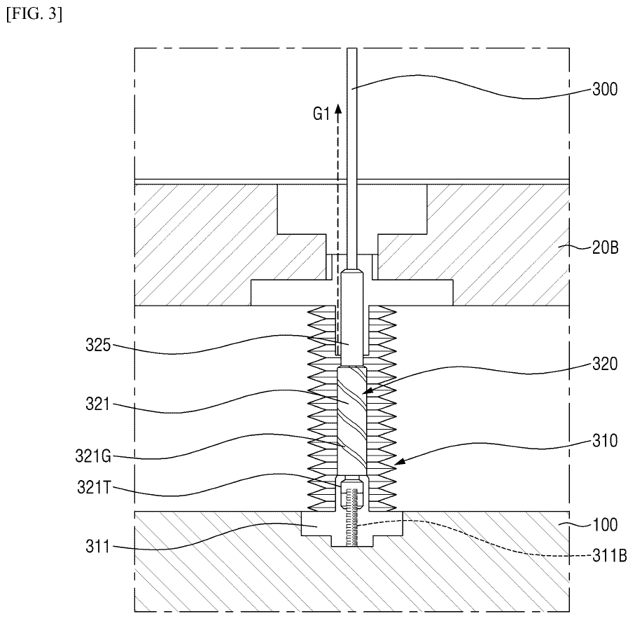

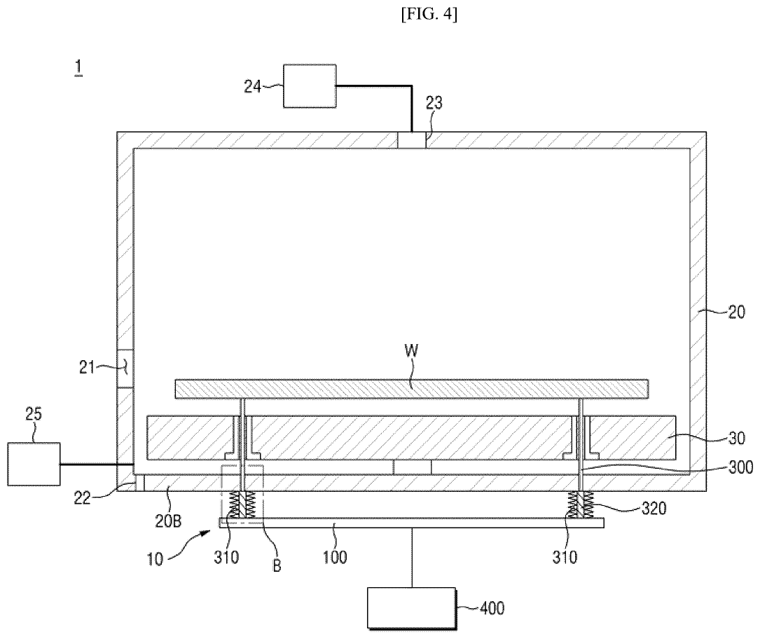

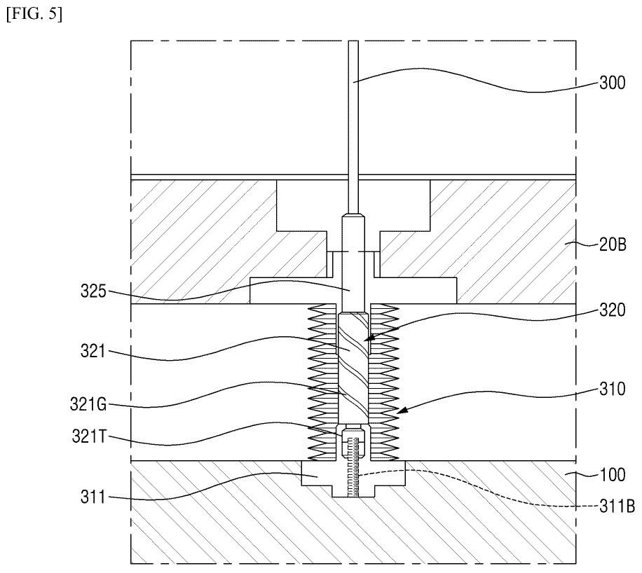

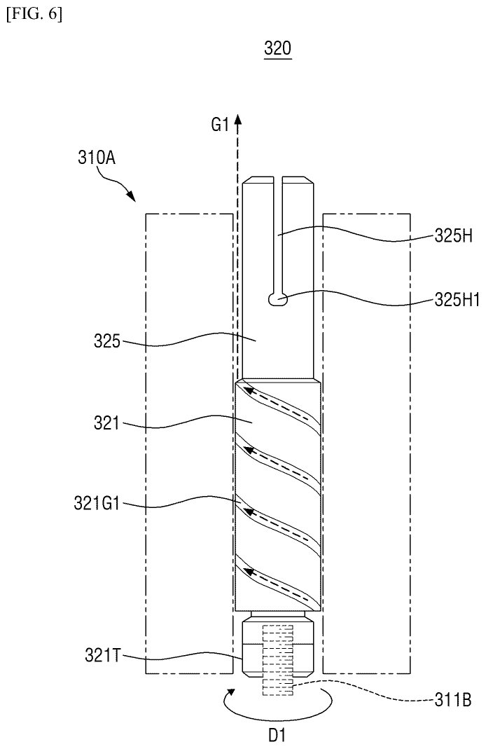

FIG. 2 is a view illustrating a substrate processing apparatus provided with a substrate lifting apparatus according to some exemplary embodiments of the present disclosure and FIG. 3 is a view illustrating area A of FIG. 2. FIG. 4 is a view illustrating a state in which a substrate is lifted in the substrate processing apparatus provided with the substrate lifting apparatus according to some exemplary embodiments of the present disclosure and FIG. 5 is a view illustrating area B of FIG. 4. In addition, FIG. 6 is a view illustrating a pin holder of a substrate lifting apparatus according to a first exemplary embodiment of the present disclosure;

First, referring to FIGS. 2 and 4, the substrate processing apparatus 1 according to an exemplary embodiment of the present disclosure may include a substrate lifting apparatus 10, a chamber 20, and a substrate support unit 30.

First, the chamber 20 may form a processing space where the substrate W is processed. The processing space of the chamber 20 may be generally maintained in a vacuum atmosphere when processing the substrate W. For example, the processing space may be an etching processing space in which the substrate W is etched with plasma. An opening 21 through which the substrate W enters and exits may be formed in a side wall of the chamber 20, and a door (not illustrated) may be provided in the opening 21. An exhaust hole 22 may be formed in a bottom surface 20B of the chamber 20, and a supply hole 23 through which process gas flows from a gas supply unit 24 may be formed in an upper portion of the chamber 20. Here, the process gas may be a process gas for processing the substrate with plasma.

The chamber 20 may be provided with a vacuum pump 25. The vacuum pump 25 may create a vacuum atmosphere in the processing space and an internal space of a bellows 310 connected to the processing space. When the vacuum pump 25 operates to create the vacuum atmosphere in the processing space, an air flow G1 may be formed from the inside of the bellows 310 toward the processing space in a process of discharging air in the processing space to the outside.

For example, when the air flow G1 is generated, a coupling portion of a bolt 311B may be rattled and a coupling may become loose. To prevent this, according to the present exemplary embodiment, a guide member 321G may be formed, which will be described later.

The substrate support unit 30 may support the substrate W. The substrate support unit 30 may have a support surface that supports the substrate W. The substrate support unit 30 may support the substrate W and chum the supported substrate W. For example, an electrostatic plate (not illustrated) may be provided within the substrate support unit 30 and may be an electrostatic chuck that churns the substrate W using electrostatic force.

Alternatively, various modifications are possible, such as the substrate support unit 30 chucking the substrate W using a vacuum suction method. In addition, a through hole (not illustrated) through which a lift pin 300 penetrates may be formed in the substrate support unit 30 so that a height of the substrate W on the substrate support unit 30 may be changed.

Referring to FIGS. 2 to 6, the substrate lifting apparatus 10 may lift the substrate W inside the chamber 20. The substrate lifting apparatus 10 may include a lift pin 300 and a driver 400 that may be lifted and lowered by a plate 100.

The plate 100 is configured to change a vertical height of the lift pin 300 by changing a relative height with the chamber 20 by the driver 400. The plate 100 may support the bellows 310 and the pin holder 320. The plate 100 may be coupled to a lower end of the bellows 310.

The lift pin 300 may be in contact with the substrate W and move the substrate W in a vertical direction. The lift pin 300 may be installed on an upper surface of the plate 100.

The lift pin 300 may have a structure that extends in an upper direction from the inside of the pin holder 320 and stands upright on the plate 100.

A plurality of lift pins 300 may be disposed on the upper surface of the plate 100. The plurality of lift pins 300 may be disposed at an edge of the plate 100, but are not limited thereto. The vicinity of the lift pin 300 may be isolated from the outside by the bellows 310.

The pin holder 320, which is a medium connecting the bellows 310/plate 100 and the lift pin 300, may surround the lift pin 300. As an example, the lift pin 300 may be inserted into the pin holder 320 from the top to the bottom of the pin holder 320, and a lower end of the lift pin 300 may be fixed to the inside of the pin holder 320.

For example, the pin holder 320 may include an upper area 325 positioned above and a lower area 321 positioned below the upper area 325. The upper area 325 may have a smaller diameter than the lower area 321, but is not limited thereto. A cut groove 325H cut from the top to the bottom may be formed in the upper area 325 of the pin holder 320 to facilitate the insertion of the lift pin 300. An expansion hole 325H1 whose cut area is expanded at a lower end may be formed in the cut groove 325H.

The pin holder 320 may be provided with a tab 321T at a lower end of the lower area 321. The tab 321T may have a thread corresponding to a thread of the bolt 311B formed on the inside so as to be coupled to the bellows 310 via the bolt 311B. In addition, the guide member 321G may not be formed in the upper area 325 of the pin holder 320 but only in the lower area 321 thereof, but is not limited thereto.

The bellows 310 may surround the pin holder 320 on which the lift pin 300 is installed. The bellows 310 may have a corrugated pipe shape, but is not limited thereto. By isolating the vicinity of the pin holder 320 to which the lift pin 300 is coupled from the outside when the lift pin 300 penetrates through the chamber 20 and is in contact with the substrate W, the bellows 310 may block the chamber 20 through which the lift pin 300 penetrates from being exposed to the outside by the substrate lifting apparatus 10, thereby allowing the processing space to be sealed.

In other words, the bellows 310 may be disposed on the bottom surface 20B of the chamber 20 through which the lift pin 300 penetrates, and may isolate the inside and outside of the chamber 20 so that the inside of the chamber 20 is maintained in a vacuum.

The driver 400 may be, for example, an actuator and may drive the substrate lifting apparatus 10. As an example, the driver 400 may be implemented in a pneumatic method in which the plate 100 is lifted by supplying compressed air so that the lift pin 300 lifts the substrate W, or the plate 100 is lowered by discharging the compressed air, but is not limited thereto.

Hereinafter, an operation of the substrate lifting apparatus 10 will be described with reference to FIGS. 2 to 5.

Referring to FIGS. 2 and 3, while the substrate W is being processed inside the chamber 20, the substrate lifting apparatus 10 may lower the substrate W so that the substrate W is disposed on the substrate support unit 30. For example, the plate 100 is lowered by the driver 400. Accordingly, the lift pin 300 supported by the plate 100 may be lowered. The lift pin 300 in contact with the substrate W is lowered so as not to protrude above the substrate support unit 30, and thus the substrate W may be disposed on the substrate support unit 30.

Referring to FIGS. 4 and 5, the substrate lifting apparatus 10 may lift the substrate W from the substrate support unit 30. For example, the plate 100 is lifted by the driver 400. Accordingly, the lift pin 300 supported by the plate 100 is lifted, and at this time, the lift pin 300 protrudes above the substrate support unit 30. As the lift pin 300 in contact with the substrate W is lifted, the substrate W may be lifted from the substrate support unit 30. In addition, when the plate 100 is lifted, the bellows 578 between the plate 100 and the bottom surface 20B of the chamber 20 may be pressed by the plate 100 and contracted.

The relative height of the plate 100 and the lift pin 300, which are lifted and lowered in this way, with respect to the chamber 20 changes. The bellows 578 is installed at a connection portion between the plate 100 and the lift pin 300 so that airtightness of the connection portion between the plate 100 and the lift pin 300 is maintained regardless of the lifting or lowering of the plate 100 and the lift pin 300.

Hereinafter, a structure for preventing the pin holder 320 of the substrate lifting apparatus 10 from being released will be described with reference to the drawings.

Referring to FIG. 6, the pin holder 320 according to the first exemplary embodiment of the present disclosure may be formed with a guide member 321G (e.g., a spiral groove 321G1).

The pin holder 320 may be coupled with the bolt 311B and fastened to an inner lower portion of the bellows 310 (or an upper surface of the plate 100). As an example, the bolt 311B may be fixed to the inner lower portion of the bellows 310, and may have a structure in which the pin holder 320 is fixed to the bellows 310 by rotating the pin holder 320 and being coupled to the bolt 311B.

The guide member 321G of the pin holder 320 may guide the air flow G1. As an example, the guide member 321G may guide the air flow G1 generated when the processing space is formed in a vacuum atmosphere, that is, the air is discharged to the outside to form the vacuum atmosphere, or the air in the processing space is discharged to the outside through the exhaust hole 22.

In the process where the air flow G1 is guided by the guide member 321G, a pressing force (pressing force generated by the air flow G1) may act on the guide member 321G, and as a result, the pin holder 320 rotates, that is, the pin holder 320 rotates in a direction in which it is coupled to the bolt 311B, thereby preventing or reducing the loosening of the coupling with the bolt 311B. If the loosening of the bolt 311B is prevented, particles that may be generated in a process in which the bolt 311B is loosened may also be reduced.

Here, the pressing force generated by the air flow G1 flows toward an upper portion of the guide member 321G in a process of moving the air around the bellows 310, and at this time, may mean a force pushing an inner surface, one surface, and/or the other surface of the guide member 321G.

The guide member 321G is formed along an outer peripheral surface of the pin holder 320, and may form a spiral shape inclined upward in the direction in which the air flow G1 is guided in a direction in which the pin holder 320 is assembled to the bolt 311B. That is, the guide member 321G may form a spiral shape inclined upward in the same direction as an assembly direction D1 of the bolt 311B. Here, the assembly direction D1 may be a clockwise or counterclockwise direction.

For example, the guide member 321G may include a concave spiral groove 321G1 along the circumference of the pin holder 320. The spiral groove 321G1 may be formed by machining a groove in a general pin holder 320. Here, the bellows 310 is formed so that the inner side of the bellows 310 is in contact with or close to the outer peripheral surface of the pin holder 320 (see 310A in FIG. 6, an area including the bellows 310), so that the air in the processing space may be further collected in the spiral groove 321G1, but is not limited thereto.

In this way, when the air flow G1 formed between the pin holder 320 and the bellows 310 is guided along the spiral of the guide member 321G and the air flows out of the processing space, the pressing force may be generated in the air flow G1 through the process of forming a vacuum atmosphere while forming a pressure lower than atmospheric pressure, for example. As a result, since the pin holder 320 may be turned in the direction in which the pin holder 320 is assembled in the process in which the air flows out of along the spiral of the guide member 321G, the pin holder 320 may be prevented from loosening from the bolt 311B.

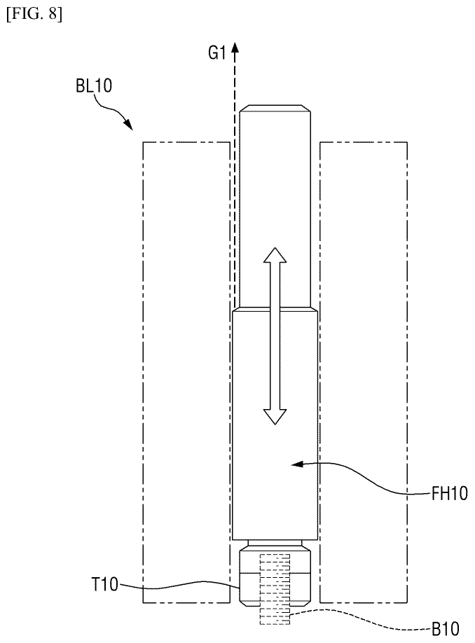

That is, FIG. 8 is a view illustrating a pin holder according to a comparative example. Referring to FIG. 8, BL10, not described here, is the area where the bellows is provided, and when the air flow G1 is formed inside the bellows 310, the pin holder FH10 on which the guide member 321G is not formed may be moved up and down in the vertical direction by the force generated by the air flow G1, the tab T10 coupled to the bolt B10 may become loose as the screw coupling is loosened.

On the other hand, since the pin holder 320 according to the present disclosure may rotate in the assembly direction D1 due to the pressing force generated by the air flow G1, in the process of guiding the air flow G1 along the guide member 321G when the air flow G1 is formed, the loosening of the screw coupling may be prevented or reduced.

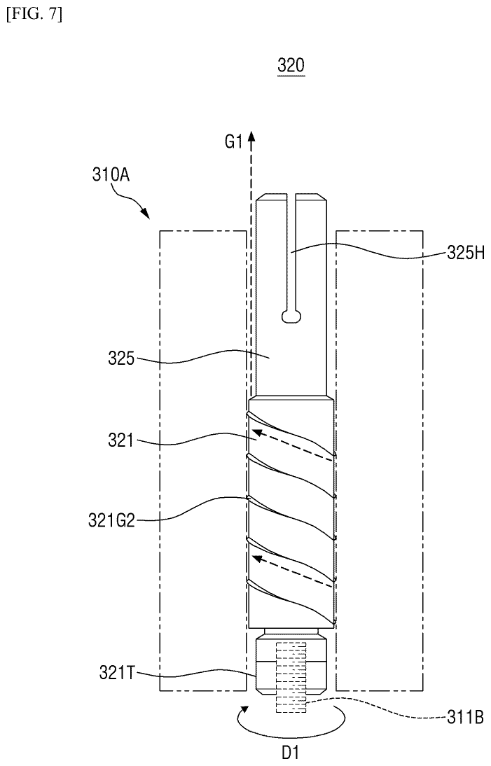

Hereinafter, a modified example of the present exemplary embodiment will be described with reference to FIG. 7, and redundant descriptions of the same configuration that perform the same function will be omitted.

FIG. 7 is a view illustrating a pin holder of a substrate lifting apparatus according to a second exemplary embodiment of the present disclosure. Differences from those described using FIGS. 2 to 6 will be mainly described with reference to FIG. 7.

Referring to FIG. 7, in a substrate lifting apparatus 10 according to a second exemplary embodiment of the present disclosure, the pin holder 320 may be formed with the guide member 321G in the same manner as or similar manner to the substrate lifting apparatus 10 of the first exemplary embodiment.

However, the guide member 321G of the second exemplary embodiment is different in that it includes a spiral wing 321G2, which is different from the spiral groove 321G1 of the first exemplary embodiment. Unlike the spiral groove 321G1 forming a concave groove structure, the wing 321G2 may extend/protrude in an outward direction along the circumference of the pin holder 320. To prevent the wing 321G2 from excessively increasing a load on the pin holder 320 and reducing a rotational force, a radius of the wing 321G2 may be formed to be smaller than a radius of the pin holder 320.

In the wing 321G2 of the second exemplary embodiment, since the pressing force generated by the air flow G1 pushes the wing 321G2 in a spiral direction while the air flow G1 is guided by the pin holder 320 in the same manner as or similar manner to the spiral groove 321G1 of the first exemplary embodiment, the pin holder 320 may be rotated in the direction in which the pin holder 320 is assembled, and thus loosening of the pin holder 320 may be prevented or minimized.

In addition, in the bellows 310 of the second exemplary embodiment, the inner side of the bellows 310 may be formed in contact with or close to an edge of the wing 321G2 so that the air in the processing space may be collected in the wing 321G2 and moved while the inner side of the bellows 310 does not interfere with the wing 321G2.

In addition, another exemplary embodiment is possible by combining the pin holder 320 of the first exemplary embodiment and the pin holder 320 of the second exemplary embodiment of the present disclosure. That is, the guide member 321G of the pin holder 320 may be formed with the spiral groove 321G1 and the wing 321G2. For example, the wing 321G2 may be formed along an upper end of the spiral groove 321G1.

It is illustrated in the present exemplary embodiment that the substrate lifting apparatus 10 is disposed outside the chamber 20 and lifts the substrate W, but the exemplary embodiment is not limited thereto. As another example, the substrate lifting apparatus 10 may lift the substrate W while being disposed below the substrate support unit 30 inside the chamber 20.

Although the exemplary embodiments of the present disclosure have been described with reference to the accompanying drawings, those of ordinary skill in the art to which the present disclosure pertains will understand that the present disclosure may be embodied in other specific forms without changing the technical spirit or essential features thereof. Therefore, it should be understood that the exemplary embodiments described above are illustrative in all aspects and not restrictive.

What is claimed is:

1. A substrate lifting apparatus comprising:
a lift pin penetrating through a substrate support unit supporting a substrate in a processing space and lifting and lowering the substrate;
a pin holder into which a lower portion of the lift pin is inserted; and
a bellows surrounding the pin holder,
wherein the pin holder is formed with a guide member whose lower portion is coupled with a bolt and guiding an air flow generated inside the bellows in a direction of the processing space.

2. The substrate lifting apparatus of claim 1, wherein the guide member is formed along an outer peripheral surface of the pin holder, and forms a spiral shape inclined upward in the same direction as a direction in which the pin holder is assembled to the bolt.

3. The substrate lifting apparatus of claim 2, wherein the guide member includes a concave spiral groove along a circumference of the pin holder.

4. The substrate lifting apparatus of claim 3, wherein the bellows is formed such that an inner side of the bellows is in contact with the outer peripheral surface of the pin hold.

5. The substrate lifting apparatus of claim 1, wherein the guide member includes a spiral wing extending in an outward direction along a circumference of the pin holder.

6. The substrate lifting apparatus of claim 5, wherein the wing has a radius smaller than a radius of the pin holder.

7. The substrate lifting apparatus of claim 5, wherein the bellows is formed such that an inner side of the bellows is in contact with an edge of the wing.

8. The substrate lifting apparatus of claim 1, wherein the pin holder includes an upper area positioned above and a lower area positioned below the upper area,
a cut groove is formed in the upper area of the pin holder from top to bottom to facilitate the insertion of the lift pin, and
the guide member is not formed in the upper area but only in the lower area.

9. The substrate lifting apparatus of claim 8, wherein an expansion hole whose cut area is expanded at a lower end is formed in the cut groove.

10. The substrate lifting apparatus of claim 1, wherein the pin holder has a thread formed on an inner peripheral surface to be coupled to the bolt and is provided with a tab positioned at a lower end.

11. The substrate lifting apparatus of claim 1, wherein the pin holder is coupled with the bolt at an inner lower portion of the bellows, or is coupled with the bolt on a plate provided to be movable up and down for lifting and lowering the lift pin.

12. A substrate processing apparatus comprising:
a chamber in which a processing space is formed;
a substrate support unit provided in the processing space and supporting a substrate;
a vacuum pump creating a vacuum atmosphere in the processing space; and
the substrate lifting apparatus of claim 1.

13. The substrate processing apparatus of claim 12, further comprising:
a plate provided to be movable up and down for lifting and lowering the lift pin and supporting the bellows and the pin holder; and
an actuator lifting and lowering the plate.

14. The substrate processing apparatus of claim 12, wherein the chamber is formed with an opening through which the substrate enters and exits, and an exhaust hole through which by-products generated in the processing space are discharged to the outside,
the processing space is created in a vacuum atmosphere by the vacuum pump, and
the pin holder rotates in a direction in which the pin holder is coupled to the bolt by a pressing force generated by an air flow in a process in which the processing space is created in the vacuum atmosphere or the air flow generated as air in the processing space is discharged to the outside through the exhaust hole moves along the guide member.

15. The substrate processing apparatus of claim 12, wherein the processing space forms an etching processing space for etching the substrate with plasma.

16. A substrate processing apparatus comprising:
a chamber in which a processing space is formed where a substrate is processed by plasma etching, an opening through which the substrate enters and exits, and an exhaust hole through which by-products generated in the processing space are discharged to the outside are formed;
a substrate support unit provided in the processing space and supporting the substrate;
a vacuum pump creating a vacuum atmosphere in the processing space;
a substrate lifting apparatus lifting and lowering the substrate; and
a plate provided below a bottom surface of the chamber to be movable up and down for lifting and lowering the substrate lifting apparatus,
wherein the substrate lifting apparatus includes:
a lift pin penetrating through the substrate support unit and the bottom surface of the chamber and lifting and lowering the substrate;
a pin holder into which a lower portion of the lift pin is inserted, supported on the plate, and including an upper area positioned above and a lower area positioned below the upper area, a cut groove being formed in the upper area from top to bottom to facilitate the insertion of the lift pin; and
a bellows surrounding the pin holder, having an inner side in contact with an outer peripheral surface of the pin holder, and supported on the plate, and
the pin holder is fastened to an inner lower portion of the bellows by coupling a lower portion with a bolt, and a concave spiral groove formed along the outer peripheral surface of the pin holder to guide an air flow generated when the processing space is created in a vacuum atmosphere or when air of the processing space is discharged to the outside through the exhaust hole, and having a spiral shape inclined upward in the same direction as a direction in which the pin holder is assembled to the bolt is provided in the lower area of the pin holder.
